(19) United States
(12) Patent Application Publication
(10) Pub. No.: US 2022/0317004 A1
(43) Pub. Date: Oct. 6, 2022

(54) A SYSTEM AND A METHOD FOR MONITORING MATERIAL FATIGUE

(71) Applicant: LAPPEENRANNAN-LAHDEN TEKNILLINEN YLIOPISTO LUT, Lappeenranta (FI)

(72) Inventors: Timo BJÖRK, Lappeenranta (FI); Antti AHOLA, Lappeenranta (FI)

(21) Appl. No.: 17/634,886

(22) PCT Filed: Jun. 24, 2020
(86) PCT No.: PCT/FI2020/050452

§ 371 Date: Feb. 11, 2022

(30) Foreign Application Priority Data
Aug. 21, 2019 (FI) 20195690

(51) Int. Cl. G01N 3/20; G01M 5/00; G06F 30/23

(52) U.S. Cl. CPC G01N 3/20; G01M 5/0033; G06F 30/23

(57) ABSTRACT

A system for monitoring fatigue of a mechanical structure includes a memory storing response values each associated with one of predetermined stress ranges and one of predetermined mean stresses. Each response value expresses an upper limit for number of cycles of stress at a predetermined observation point of the mechanical structure in a situation where the cycles have the stress range and the mean stress related to the response value. The system includes processing equipment for updating, for each response value, a stress history value expressing number of cycles occurred in a time-trend of the stress and having the stress range and the mean stress related to the response value. A fatigue damage sum is updated based on the response values and the stress history values. The fatigue damage sum expresses cumulated fatigue damage of the mechanical structure and can be used for real-time fatigue monitoring.

### FIELD OF TECHNOLOGY

The disclosure relates generally to monitoring material fatigue. More particularly, the disclosure relates to a system and a method for monitoring fatigue of a mechanical structure. Furthermore, the disclosure relates to a computer program for monitoring fatigue of a mechanical structure.

### BACKGROUND

In many cases, a mechanical structure is subjected to cyclic mechanical loading which may cause fatigue in materials of the mechanical structure. The mechanical structure can be for example a part of a working machine such as e.g. a crane, a part of a vehicle, or a part of some other device, or a whole device. If the above-mentioned cyclic mechanical loading is above a certain threshold, microscopic cracks will begin to form at stress concentrators such as for example surfaces, persistent slip bands “PSB”, interfaces of constituents in a case of composites, and grain interfaces in a case of metals. After crack initiation, the crack will propagate, and eventually the mechanical structure will finally fracture. The shape of the mechanical structure will significantly affect the fatigue strength. For example, square holes and sharp corners will lead to elevated local stresses where fatigue cracks can initiate. Instead, round holes and smooth transitions and fillets will increase the fatigue strength of the mechanical structure. In welded metal structures, areas adjacent to welded joints are often critical since a local geometry and existence of high residual stress and welding deformations in welded joints are often suboptimal from the viewpoint of the fatigue strength.

An inherent challenge related to damages caused by fatigue is that the above-mentioned microscopic cracks are typically not recognized during a use of a mechanical structure. A further challenge is that the crack propagation will accelerate in accordance with an increasing crack length and therefore the mechanical structure may fracture even if the loading remains unchanged. Thus, in many cases, fatigue in materials of mechanical structures may cause expensive production shutdowns. Therefore, there is a need for techniques for monitoring fatigue in a mechanical structure during a lifetime of the mechanical structure.

### SUMMARY

The following presents a simplified summary in order to provide a basic understanding of some aspects of various invention embodiments. The summary is not an extensive overview of the invention. It is neither intended to identify key or critical elements of the invention nor to delineate the scope of the invention. The following summary merely presents some concepts of the invention in a simplified form as a prelude to a more detailed description of exemplifying embodiments of the invention.

In accordance with the present invention, there is provided a new system for monitoring fatigue of a mechanical structure that can be e.g. a part of a working machine such as e.g. a crane, a part of a vehicle, or a part of some other device, or a whole device.

A system according to the invention comprises memory equipment storing a database that contains predetermined response values each being associated with one of predetermined stress ranges, i.e. stress variation ranges, and one of predetermined mean stresses, each of the response values expressing an upper limit for number of cycles of stress at a predetermined observation point of the mechanical structure in a situation in which the cycles have the predetermined stress range and the predetermined mean stress related to the response value under consideration, where the upper limit corresponds to a predetermined survival probability of the mechanical structure.

The system further comprises processing equipment configured to:
repeatedly update, for each of the above-mentioned response values, a stress history value expressing number of cycles occurred in a time-trend of the stress and having the predetermined stress range and the predetermined mean stress related to the response value under consideration, and
repeatedly update a fatigue damage sum based on the response values and the stress history values related to the response values.

The fatigue damage sum expresses cumulated fatigue damage of the mechanical structure, and therefore the fatigue damage sum can be used for real-time fatigue monitoring during a lifetime of the mechanical structure. A system according to an advantageous embodiment of the invention is suitable for monitoring fatigue of a mechanical structure in real time and during usage of the mechanical structure.

It is worth noting that computations carried out for updating the above-mentioned fatigue damage sum are not necessarily carried out with stress values, but as well the computations can be carried out with values of another quantity related to the stress. For example, each response value can be associated with one of predetermined strain ranges and one of predetermined mean strains. The response value is however indirectly associated with one of predetermined stress ranges and one of predetermined mean stresses because the strain is related to the stress via a deterministic rule.

In accordance with the present invention, there is provided also a new method for monitoring fatigue of a mechanical structure. The method comprises:
maintaining a database containing predetermined response values each being associated with one of predetermined stress ranges and one of predetermined mean stresses, each of the response values expressing an upper limit for number of cycles of stress at a predetermined observation point of the mechanical structure in a situation in which the cycles have the predetermined stress range and the predetermined mean stress related to the response value under consideration, the upper limit corresponding to a predetermined survival probability of the mechanical structure,
repeatedly updating, for each of the above-mentioned response values, a stress history value expressing number of cycles occurred in a time-trend of the stress and having the predetermined stress range and the predetermined mean stress related to the response value under consideration, and
repeatedly updating a fatigue damage sum based on the response values and the stress history values related to the response values.

In accordance with the invention, there is provided also a new computer program for monitoring fatigue of a mechanical structure. The computer program comprises computer executable instructions for controlling programmable processing equipment to:
retrieve data from a database containing predetermined response values each being associated with one of predetermined stress ranges and one of predetermined mean stresses, each of the response values expressing an upper limit for number of cycles of stress at a predetermined observation point of the mechanical structure in a situation in which the cycles have the predetermined stress range and the predetermined mean stress related to the response value under consideration, the upper limit corresponding to a predetermined survival probability of the mechanical structure,
repeatedly update, for each of the response values, a stress history value expressing number of cycles occurred in a time-trend of the stress and having the predetermined stress range and the predetermined mean stress related to the response value under consideration, and
repeatedly update a fatigue damage sum based on the response values and the stress history values related to the response values.

In accordance with the invention, there is provided also a new computer program product. The computer program product comprises a non-volatile computer readable medium, e.g. a compact disc “CD”, encoded with a computer program according to the invention.

Various exemplifying and non-limiting embodiments are described in accompanied dependent claims.

Exemplifying and non-limiting embodiments both as to constructions and to methods of operation, together with additional objects and advantages thereof, will be best understood from the following description of specific exemplifying embodiments when read in conjunction with the accompanying drawings.

The verbs “to comprise” and “to include” are used in this document as open limitations that neither exclude nor require the existence of also un-recited features. The features recited in the accompanied dependent claims are mutually freely combinable unless otherwise explicitly stated. Furthermore, it is to be understood that the use of “a” or “an”, i.e. a singular form, throughout this document does not exclude a plurality.

### BRIEF DESCRIPTION OF THE FIGURES

Exemplifying and non-limiting embodiments and their advantages are explained in greater detail below in the sense of examples and with reference to the accompanying drawings, in which:

FIG. 1 shows a functional block diagram of a system according to an exemplifying and non-limiting embodiment for monitoring fatigue of a mechanical structure,

FIGS. 2a and 2b illustrate exemplifying ways to visualize results obtained with a system according to an exemplifying and non-limiting embodiment, and

FIG. 3 shows a flowchart of a method according to an exemplifying and non-limiting embodiment for monitoring fatigue of a mechanical structure.

### DESCRIPTION OF EXEMPLIFYING AND NON-LIMITING EMBODIMENTS

The specific examples provided in the description below should not be construed as limiting the scope and/or the applicability of the accompanied claims. Lists and groups of examples provided in the description are not exhaustive unless otherwise explicitly stated.

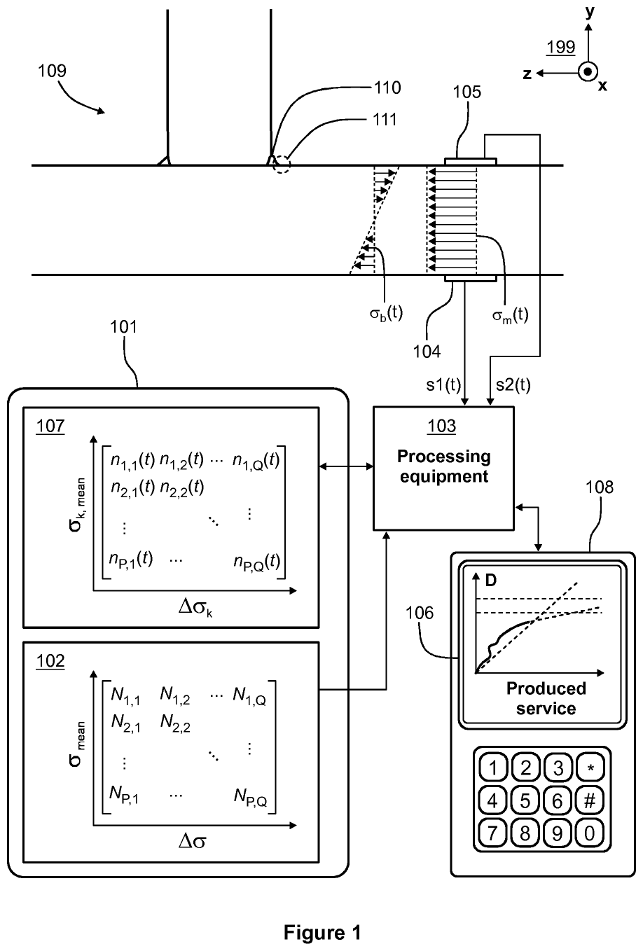

FIG. 1 shows a functional block diagram of a system according to an exemplifying and non-limiting embodiment for monitoring fatigue of an exemplifying mechanical structure 109. In the exemplifying situation shown in FIG. 1, the mechanical structure 109 comprises a welded T-joint 110, and fatigue at an observation point 111 of the mechanical structure 109 is monitored. It is to be noted that the mechanical structure 109 is shown for illustrative purposes only, and the system illustrated in FIG. 1 is applicable with many different mechanical structures to be monitored.

The system comprises memory equipment 101 storing a database 102 that contains predetermined response values N_{1,1}, . . . , N_{P,Q}. Each of the predetermined response values N_{1,1}, . . . , N_{P,Q} is associated with one of predetermined stress ranges Δσ₁, . . . , Δσ_{,Q} and with one of predetermined mean stresses σ_{1,mean}, . . . , σ_{P,mean}. Each response value expresses an upper limit for number of cycles of stress σ(t) at the observation point 111 of the mechanical structure 109 in a situation in which the cycles have the predetermined stress range Δσ and the predetermined mean stress σₘₑₐₙ related to the response value under consideration. The upper limit corresponds to a predetermined survival probability of the mechanical structure 109 in the above-described situation. Each of the predetermined response values N_{1,1}, . . . , N_{P,Q} can be estimated based on the fatigue performance of the mechanical structure 109. In general, at the positive side, a sum of the mean stress and the amplitude i.e. the stress range/2, converted to nominal stress level, should not exceed the yield strength of material under consideration. The maximum allowable compressive nominal membrane stress, respectively, should not exceed the yield strength at the compressive side. In an exemplifying case where a thin and slender mechanical structure is under monitoring, the maximum allowable compressive stress related to the buckling capacities, such as plate buckling, flexural, or lateral buckling of columns, should not be exceeded.

Each response value N_{k,q}, where k=1, 2, . . . , P and q=1, 2, . . . , Q can be computed for example according to the following equation:

$${N}_{k , q} = \frac{{C}_{ref}}{{( \frac{Δσ q}{\sqrt{1 - {R}_{local}}} )}^{{m}_{ref}}} , \qquad ( 1 )$$

where C_{ref} is a fatigue performance that is specific to the mechanical structure under consideration and corresponds to a selected survival probability, Δσ_{q} is the stress range at the observation point of the mechanical structure, and m_{ref} is a model parameter i.e. the slope of the S-N curve e.g. 5.85. R_{local} is a local stress ratio at the observation point, e.g. a notch, of the mechanical structure:

$${R}_{local} = \frac{{σ}_{mean} - Δσ / 2}{{σ}_{mean} + Δσ / 2} , \qquad ( 2 )$$

where σₘₑₐₙ and Δσ are the mean stress and the stress range, respectively, at the observation point of the mechanical structure, considering the material elastoplastic behavior.

The above-mentioned local stress ratio R_{local} and subsequently the response value N_{k,q} depend on, among others, material strength, residual stresses within the mechanical structure both in as-welded or post treated conditions, geometry and dimensions of the mechanical structure, welded joint and/or cut edge parameters, such as e.g. weld toe or root side geometry for a welded joint and surface quality for a cut edge.

Theoretical background related to the above-presented equations 1 and 2 can be found in the publication: Timo Nykänen and Timo Björk: Assessment of fatigue strength of steel buttwelded joints in as-welded condition—Alternative approaches for curve fitting and mean stress effect analysis, Lappeenranta University of Technology, Laboratory of Steel Structures, Marine Structures 44, 2015, pp. 288-310, Elsevier Ltd, and in the publication: Timo Nykänen and Timo Björk: A new proposal for assessment of the fatigue strength of steel buttwelded joints improved by peening under constant amplitude tensile loading, School of Energy Systems, Lappeenranta University of Technology, Wiley Publishing Ltd. Fatigue Fract Engng Mater Struct, 2016, 39, pp. 566-582. It is to be noted that the above-mentioned response values N_{1,1}, . . . , N_{P,Q} can be obtained with any suitable method, and therefore the invention is not limited to any particular method for obtaining the response values N_{1,1}, . . . , N_{P,Q}.

The above-mentioned mean stress considers advantageously the average stress level of external stress range and the effect of residual stresses. The third level, i.e. the tertiary, stress as notch stress level residual stresses are advantageously considered at notch stresses, and the secondary as structural level stresses are advantageously multiplied by notch factors. Also, the relaxation of the residual stresses can be considered, and the analysis can apply the relaxed stress values.

The system comprises processing equipment 103 configured to repeatedly update, for each of the above-mentioned response values N_{1,1}, . . . , N_{P,Q}, a corresponding stress history value n_{1,1}(t), . . . , n_{P,Q}(t) that expresses number of cycles which have occurred in the time-trend of the stress σ(t) and which have the predetermined stress range and the predetermined mean stress related to the response value under consideration. The stress history values n_{1,1}(t), . . . , n_{P,Q}(t) are presented as functions of time t because their values develop along with the time. The update rate can be e.g. in the range from 0.01 Hz to 20 Hz. In other words, a time interval between successive updates of the stress history values n_{1,1}(t), . . . , n_{P,Q}(t) can be from 50 millisecond to 100 seconds. In the exemplifying system illustrated in FIG. 1, the memory equipment 101 stores a database 107 that contains the stress history values n_{1,1}(t), . . . , n_{P,Q}(t).

In a system according to an exemplifying and non-limiting embodiment, the processing equipment 103 is configured to run the Rainflow-counting algorithm to update the stress history values n_{1,1}(t), . . . , n_{P,Q}(t) based on the time-trend of the stress σ(t) at the observation point 111 of the mechanical structure 109. The Rainflow-counting algorithm, also known as the “Rain-flow counting method”, is commonly used in fatigue analyses and monitoring to reduce a spectrum of time-varying stress into a set of cycle counts corresponding to a given set of mean values and a given set of variation ranges. More detailed information about the Rainflow-counting algorithm can be found e.g. in the publication M. Matsuishi and T. Endo: Fatigue of metals subjected to varying stress, Japan Society of Mechanical Engineering 1968. It is to be noted that there are many cycle-counting algorithms for fatigue analyses and monitoring, and therefore the invention is not limited to any specific cycle-counting algorithm.

The processing equipment 103 is configured to repeatedly update a fatigue damage sum D based on the response values N_{1,1}, . . . , N_{P,Q} and the stress history values n_{1,1}(t), . . . , n_{P,Q}(t) related to the response values. The fatigue damage sum D expresses cumulated fatigue damage of the mechanical structure 109 and it can be used for estimating a remaining service producible by the mechanical structure. The update rate can be e.g. in the range from 0.01 Hz to 20 Hz. In other words, a time interval between successive updates of the fatigue damage sum D can be from 50 millisecond to 100 seconds.

In a system according to an exemplifying and non-limiting embodiment, the processing equipment 103 is configured to compute the fatigue damage sum D according to the Palmgren-Miner damage accumulation formula:

$$D = {\sum }_{\begin{matrix}i = 1 , P \\ j = 1 , Q\end{matrix}} \frac{{n}_{i , j} ( t )}{{N}_{i , j}} . \qquad ( 3 )$$

A system according to an exemplifying and non-limiting embodiment comprises a display element 106, and the processing equipment 103 is configured to control the display element 106 to show growth of the fatigue damage sum D as a function of cumulative service produced by the mechanical structure 109. The display element 106 can be e.g. a part of a user interface 108 of the system. The cumulative service produced by the mechanical structure 109 can be for example a cumulative service time, a cumulative distance traversed by a vehicle or another device comprising the mechanical structure, a cumulative mass of loads transferred or lifted by a device comprising the mechanical structure, a cumulative product of transferred mass and transfer distance e.g. ton-kilometers, or some other quantity indicative of the cumulative service produced by the device comprising the mechanical structure 109.

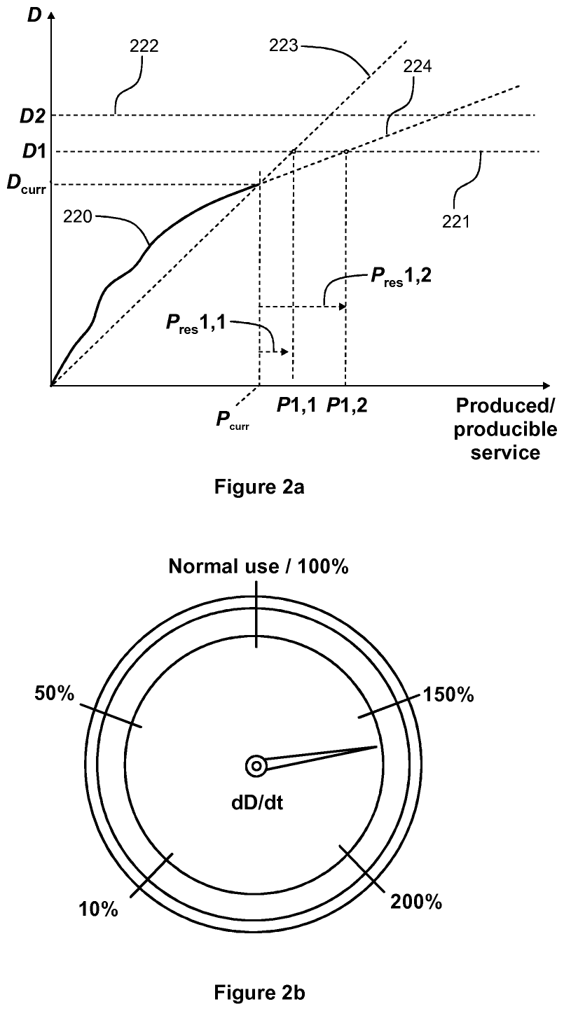

In a system according to an exemplifying and non-limiting embodiment, the processing equipment 103 is configured to compute an average growth rate of the fatigue damage sum D. In FIG. 2a, the average growth rate of the fatigue damage sum D is the slope of the line 223. The processing equipment 103 is configured to estimate a remaining service Pᵣₑₛ1,1 producible by the mechanical structure 109, e.g. a remaining service time, based on: i) a current value D_{curr} of the fatigue damage sum D, ii) the above-mentioned average growth rate of the fatigue damage sum, and iii) a value of the fatigue damage sum corresponding to a predetermined damage probability. In FIG. 2a, a line 221 represents a damage sum value D1 that corresponds to a first damage probability and a line 222 represents a damage sum value D2 that corresponds to a second damage probability greater than the first damage probability. In other words, the damage sum value D1 corresponds to a greater survival probability than the damage sum value D2.

In a system according to an exemplifying and non-limiting embodiment, the processing equipment 103 is configured to compute an estimate for an instantaneous growth rate dD/dt of the fatigue damage sum D. In FIG. 2a, the instantaneous growth rate of the fatigue damage sum D is the slope of the line 224. The instantaneous growth rate can estimated e.g. as D(t₀)−D(t₋₁))/(t₀−t₋₁), where t₀ is an update moment of the fatigue damage sum D and t₋₁ is an earlier update moment of the fatigue damage sum D. Numerical derivation of the kind mentioned above is however susceptible to disturbances, and thus it can be more advantageous to fit a polynomial or some other suitable curve with the time-discrete values of the fatigue damage sum D and thereafter to estimate the instantaneous growth rate with the derivative of the polynomial or some other suitable curve. The processing equipment 103 is configured to estimate a remaining service Pᵣₑₛ1,2 producible by the mechanical structure 109 based on: i) the current value D_{curr} of the fatigue damage sum, ii) the estimate of the instantaneous growth rate of the fatigue damage sum, and iii) a value of the fatigue damage sum, e.g. D1 or D2, corresponding to a predetermined damage probability.

FIG. 2b presents a display dial that shows the instantaneous growth rate dD/dt of the fatigue damage sum D. The “Normal use/100%” corresponds to a designed i.e.

nominal instantaneous growth rate of the fatigue damage sum D so that the mechanical structure produces a designed cumulative service, e.g. a designed service time, if the instantaneous growth rate dD/dt is all the time the “Normal use/100%”.

In a system according to an exemplifying and non-limiting embodiment, the processing equipment 103 shown in FIG. 1 is configured to repeatedly estimate the stress σ(t) at the observation point 111 of the mechanical structure 109 based on data indicative of mechanical loading directed to the mechanical structure 109. The estimating rate can be e.g. in the range from 0.01 Hz to 20 Hz. In other words, a time interval between successive estimates of the stress σ(t) can be from 50 millisecond to 100 seconds. The measuring rate is advantageously significantly greater than the above-mentioned estimating rate. The measuring rate can be for example in the range from 1 Hz to 5 kHz. It is also possible that the system comprises a data interface for receiving, from an external device, data indicative of the stress σ(t) at the observation point 111 of the mechanical structure 109.

In a system according to an exemplifying and non-limiting embodiment, the processing equipment 103 is configured to compute the stress σ(t) at the observation point 111 as a weighted sum of i) membrane stress σₘ(t) and ii) bending stress σ_{b}(t) acting on an area of the mechanical structure 109 a distance away from the observation point 111 of the mechanical structure 109. The weight factors of the weighted sum are predetermined local stress concentration factors K_{t,m} and K_{t,b} defined separately for the membrane and bending stresses σₘ(t) and σ_{b}(t). Therefore, in this exemplifying case, the processing equipment 103 is configured to compute the following stress σₖ(t) according to the following equation:

σₖ(t)=K_{t,m} σₘ(t)+K_{t,b} σ_{b}(t). (4)

An exemplifying way to determine the local stress concentration factors based on the finite element analysis “FEA” is presented in the publication A. Ahola, T. Nykänen and T. Björk: Effect of loading type on the fatigue strength of asymmetric and symmetric transverse non-load carrying attachments, School of Energy Systems, Lappeenranta University of Technology, Wiley Publishing Ltd. Fatigue Fract Engng Mater Struct, 2017, 40, pp. 670-682. An exemplifying way to determine the local stress concentration factors based on an artificial neutral network “ANN” is presented in the publication M. Dabiri, M. Ghafouri, H. R. Rohani Raftar, and T. Björk: Neural network-based assessment of the stress concentration factor in a T-welded joint, Laboratory of Steel Structures, Lappeenranta University of Technology, Journal of Constructional Steel Research 128, 2017, pp. 567-578. An exemplifying way to determine the local stress concentration factors based on analytical equations is presented in the publication K. Iida and T. Uemura: Stress concentration factor formulae widely used in Japan, University of Tokyo, Fatigue Fract. Engng Mater. Struct. Vol. 19, No. 6, pp. 779-786, 1996.

In a system according to an exemplifying and non-limiting embodiment, the processing equipment 103 is configured to compute the above-mentioned membrane stress σₘ(t) and the bending stress σ_{b}(t) based on outputs s1(t) and s2(t) of strain gauges 104 and 105 attached to the mechanical structure 109. The membrane stress σₘ(t) proportional to an average (s1(t)+s2(t))/2 of the outputs of the strain gauges 104 and 105, and the bending stress σ_{b}(t) is proportional to a difference s1(t)−s2(t) of the outputs of the strain gauges 104 and 105. In many cases, there can be more than two strain gauges.

In a system according to an exemplifying and non-limiting embodiment, the processing equipment 103 is configured to compute the stress σₖ(t) at the observation point 111 of the mechanical structure 109 based on forces directed to the mechanical structure 109, an inverse of a stiffness matrix of a finite element model of at least a part of the mechanical structure 109, and element level force-displacement equations of the finite element model expressing the stress σₖ(t) as a function of nodal displacements of appropriate nodes of the finite element model. In an exemplifying case where the mechanical structure 109 operates in the linear area so that the Hooke's law is valid, the memory equipment 101 is advantageously configured to store the inverse of the stiffness matrix of the finite element model and the processing equipment 103 is advantageously configured to use the stored inverse of the stiffness matrix when repeatedly computing the stress σₖ(t). Thus, there is no need to compute the inverse of the stiffness matrix every time when the stress σₖ(t) is computed.

In a system according to an exemplifying and non-limiting embodiment, each of the response values N_{1,1}, . . . , N_{P,Q} is associated, in addition to the predetermined stress range and the predetermined mean stress, with one or more quantities descriptive of operating conditions of the mechanical structure 109. The one or more quantities may comprise for example temperature of the mechanical structure 109 because the strength capacity of the mechanical structure 109 may depend on the temperature. In this exemplifying case, the processing equipment 103 is configured to update each stress history value n_{1,1}(t), . . . , n_{P,Q}(t) to express number of cycles occurred in the time-trend of the stress so that 1) the occurred cycles have the predetermined stress range and the predetermined mean stress related to the response value under consideration and 2) the operating conditions of the mechanical structure 109 correspond to the one or more quantities related to the response value under consideration, e.g. the temperature of the mechanical structure belongs to a temperature range related to the response value under consideration and/or an effect of a corrosive environment on the material fatigue performance corresponds to a same effect of a corrosive environment related to the response value under consideration. In this exemplifying embodiment, one or more of the response values N_{1,1}, . . . , N_{P,Q} can be related to a same stress range and a same mean stress, and the one or more quantities descriptive of the operating conditions make difference between these response values.

The implementation of the processing equipment 103 can be based on one or more analogue circuits, one or more digital processing circuits, or a combination thereof. Each digital processing circuit can be a programmable processor circuit provided with appropriate software, a dedicated hardware processor such as for example an application specific integrated circuit “ASIC”, or a configurable hardware processor such as for example a field programmable gate array “FPGA”. The memory equipment 101 may comprise one or more memory circuits each of which can be for example a Random-Access Memory “RAM” circuit.

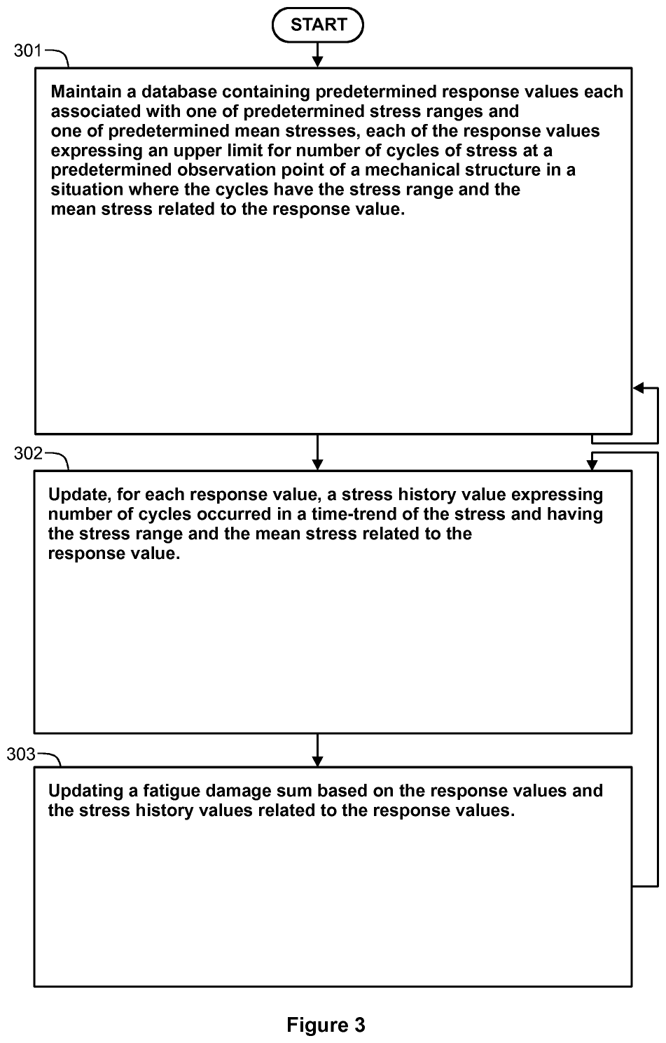

FIG. 3 shows a flowchart of a method according to an exemplifying and non-limiting embodiment for monitoring fatigue of a mechanical structure. The method comprises the following actions:
action 301: maintaining a database containing predetermined response values each being associated with one of predetermined stress ranges and one of predetermined mean stresses, each of the response values expressing an upper limit for number of cycles of stress at a predetermined observation point of the mechanical structure in a situation in which the cycles have the predetermined stress range and the predetermined mean stress related to the response value under consideration, the upper limit corresponding to a predetermined survival probability of the mechanical structure,
action 302: repeatedly updating, for each of the response values, a stress history value expressing number of cycles occurred in a time-trend of the stress and having the predetermined stress range and the predetermined mean stress related to the response value under consideration, and
action 303: repeatedly updating a fatigue damage sum based on the response values and the stress history values related to the response values, the fatigue damage sum expressing cumulated fatigue damage of the mechanical structure.

A method according to an exemplifying and non-limiting embodiment comprises repeatedly estimating the stress at the predetermined observation point of the mechanical structure based on data indicative of mechanical loading directed to the mechanical structure.

A method according to an exemplifying and non-limiting embodiment comprises computing the stress as a weighted sum of i) membrane stress and ii) bending stress acting on an area of the mechanical structure a distance away from the predetermined observation point of the mechanical structure. The weight factors of the weighted sum are predetermined local stress concentration factors defined separately for the membrane and bending stresses.

A method according to an exemplifying and non-limiting embodiment comprises computing the membrane stress and the bending stress based on outputs of strain gauges attached to the mechanical structure. The membrane stress is proportional to an average of the outputs of the strain gauges and the bending stress is proportional to a difference of the outputs of the strain gauges.

A method according to an exemplifying and non-limiting embodiment comprises computing the stress based on forces directed to the mechanical structure, an inverse of a stiffness matrix of a finite element model of at least a part of the mechanical structure, and element level force-displacement equations of the finite element model expressing the stress as a function of nodal displacements of the finite element model.

A method according to an exemplifying and non-limiting embodiment comprises storing the inverse of the stiffness matrix of the finite element model in memory equipment and using the stored inverse of the stiffness matrix when repeatedly computing the stress.

A method according to an exemplifying and non-limiting embodiment comprises computing the fatigue damage sum D according to the formula:

$$D = {\sum }_{i , j} \frac{{n}_{i , j} ( t )}{{N}_{i , j}} ,$$

where n_{i,j}(t) is the stress history value expressing the number of the cycles occurred in the time-trend of the stress and having the i^{th} predetermined stress range and the j^{th} predetermined mean stress, and N_{i,j} is the response value relating to the i^{th} predetermined stress range and to the j^{th} predetermined mean stress.

In a method according to an exemplifying and non-limiting embodiment, each of the response values is associated, in addition to the predetermined stress range and the predetermined mean stress, with one or more quantities descriptive of operating conditions of the mechanical structure e.g. temperature of the mechanical structure. In a method according to this exemplifying and non-limiting embodiment, each stress history value is updated to express number of cycles occurred in the time-trend of the stress so that 1) the occurred cycles have the predetermined stress range and the predetermined mean stress related to the response value under consideration and 2) the operating conditions of the mechanical structure correspond to the one or more quantities related to the response value under consideration.

A method according to an exemplifying and non-limiting embodiment comprises controlling a display element to show growth of the fatigue damage sum as a function of cumulative service produced by the mechanical structure.

A method according to an exemplifying and non-limiting embodiment comprises computing an average growth rate of the fatigue damage sum and estimating remaining service producible by the mechanical structure based on: i) a current value of the fatigue damage sum, ii) the average growth rate of the fatigue damage sum, and iii) a value of the fatigue damage sum corresponding to a predetermined damage probability.

A method according to an exemplifying and non-limiting embodiment comprises computing an estimate for an instantaneous growth rate of the fatigue damage sum and estimating remaining service producible by the mechanical structure based on: i) a current value of the fatigue damage sum, ii) the estimate of the instantaneous growth rate of the fatigue damage sum, and iii) a value of the fatigue damage sum corresponding to a predetermined damage probability.

A computer program according to an exemplifying and non-limiting embodiment comprises computer executable instructions for controlling programmable processing equipment to carry out actions related to a method according to any of the above-described exemplifying and non-limiting embodiments.

A computer program according to an exemplifying and non-limiting embodiment comprises software modules for monitoring fatigue of a mechanical structure. The software modules comprise computer executable instructions for controlling programmable processing equipment to:
retrieve data from a database containing predetermined response values each being associated with one of predetermined stress ranges and one of predetermined mean stresses, each of the response values expressing an upper limit for number of cycles of stress at a predetermined observation point of the mechanical structure in a situation in which the cycles have the predetermined stress range and the predetermined mean stress related to the response value under consideration, the upper limit corresponding to a predetermined survival probability of the mechanical structure,
repeatedly update, for each of the response values, a stress history value expressing number of cycles occurred in a time-trend of the stress and having the predetermined stress range and the predetermined mean stress related to the response value under consideration, and
repeatedly update a fatigue damage sum based on the response values and the stress history values related to the response values, the fatigue damage sum expressing cumulated fatigue damage of the mechanical structure.

The software modules can be for example subroutines or functions implemented with programming tools suitable for the programmable processing equipment.

A computer program product according to an exemplifying and non-limiting embodiment comprises a computer readable medium, e.g. a compact disc “CD”, encoded with a computer program according to an exemplifying and non-limiting embodiment.

A signal according to an exemplifying and non-limiting embodiment is encoded to carry information defining a computer program according to an exemplifying and non-limiting embodiment.

The specific examples provided in the description given above should not be construed as limiting the scope and/or the applicability of the accompanied claims. Lists and groups of examples provided in the description given above are not exhaustive unless otherwise explicitly stated.

1. A system for monitoring fatigue of a mechanical structure, the system comprising memory equipment storing a database containing predetermined response values each being associated with one of predetermined stress ranges and one of predetermined mean stresses, each of the response values expressing an upper limit for number of cycles of stress at a predetermined observation point of the mechanical structure in a situation in which the cycles have the predetermined stress range and the predetermined mean stress related to the response value under consideration, the upper limit corresponding to a predetermined survival probability of the mechanical structure, wherein the system comprises processing equipment configured to:
repeatedly update, for each of the response values, a stress history value expressing number of cycles occurred in a time-trend of the stress and having the predetermined stress range and the predetermined mean stress related to the response value under consideration, and
repeatedly update a fatigue damage sum based on the response values and the stress history values related to the response values, the fatigue damage sum expressing cumulated fatigue damage of the mechanical structure.

2. The system according to claim 1, wherein the processing equipment is configured to repeatedly estimate the stress at the predetermined observation point of the mechanical structure based on data indicative of mechanical loading directed to the mechanical structure.

3. The system according to claim 2, wherein the processing equipment is configured to compute the stress as a weighted sum of i) membrane stress and ii) bending stress acting on an area of the mechanical structure a distance away from the predetermined observation point of the mechanical structure, weight factors of the weighted sum being predetermined local stress concentration factors defined separately for the membrane and bending stresses.

4. The system according to claim 3, wherein the processing equipment is configured to compute the membrane stress and the bending stress based on outputs of strain gauges attached to the mechanical structure, the membrane stress being proportional to an average of the outputs of the strain gauges and the bending stress being proportional to a difference of the outputs of the strain gauges.

5. The system according to claim 4, wherein the system comprises the strain gauges.

6. The system according to claim 2, wherein the processing equipment is configured to compute the stress based on forces directed to the mechanical structure, an inverse of a stiffness matrix of a finite element model of at least a part of the mechanical structure, and element equations of the finite element model expressing the stress as a function of nodal displacements of the finite element model.

7. The system according to claim 6, wherein the memory equipment is configured to store the inverse of the stiffness matrix of the finite element model and the processing equipment is configured to use the stored inverse of the stiffness matrix when repeatedly computing the stress.

8. The system according to claim 1, wherein the processing equipment is configured to compute the fatigue damage sum D according to the formula:
$$D = {\sum }_{i , j} \frac{{n}_{i , j} ( t )}{{N}_{i , j}} ,$$
where n_{i,j}(t) is the stress history value expressing the number of the cycles occurred in the time-trend of the stress and having the i^{th} predetermined stress range and the j^{th} predetermined mean stress, and N_{i,j} is the response value relating to the i^{th} predetermined stress range and to the j^{th} predetermined mean stress.

9. The system according to claim 1, wherein:
each of the response values is associated, in addition to the predetermined stress range and the predetermined mean stress, with one or more quantities descriptive of operating conditions of the mechanical structure, and
the processing equipment is configured to update each stress history value to express number of cycles occurred in the time-trend of the stress so that the occurred cycles have the predetermined stress range and the predetermined mean stress related to the response value under consideration and the operating conditions of the mechanical structure correspond to the one or more quantities related to the response value under consideration.

10. The system according claim 9, wherein the one or more quantities descriptive of the operating conditions of the mechanical structure comprise temperature of the mechanical structure.

11. The system according to claim 1, wherein the system comprises a display element and the processing equipment is configured to control the display element to show growth of the fatigue damage sum as a function of cumulative service produced by the mechanical structure.

12. The system according to claim 1, wherein the processing equipment is configured to compute an average growth rate of the fatigue damage sum and to estimate remaining service producible by the mechanical structure based on: i) a current value of the fatigue damage sum, ii) the average growth rate of the fatigue damage sum, and iii) a value of the fatigue damage sum corresponding to a predetermined damage probability.

13. The system according to claim 1, wherein the processing equipment is configured to compute an estimate for an instantaneous growth rate of the fatigue damage sum and to estimate remaining service producible by the mechanical structure based on: i) a current value of the fatigue damage sum, ii) the estimate of the instantaneous growth rate of the fatigue damage sum, and iii) a value of the fatigue damage sum corresponding to a predetermined damage probability.

14. A method for monitoring fatigue of a mechanical structure, the method comprising:
maintaining a database containing predetermined response values each being associated with one of predetermined stress ranges and one of predetermined mean stresses, each of the response values expressing an upper limit for number of cycles of stress at a predetermined observation point of the mechanical structure in a situation in which the cycles have the predetermined stress range and the predetermined mean stress related to the response value under consideration, the upper limit corresponding to a predetermined survival probability of the mechanical structure,
repeatedly updating, for each of the response values, a stress history value expressing number of cycles occurred in a time-trend of the stress and having the predetermined stress range and the predetermined mean stress related to the response value under consideration, and
repeatedly updating a fatigue damage sum based on the response values and the stress history values related to the response values, the fatigue damage sum expressing cumulated fatigue damage of the mechanical structure.

15. A non-volatile computer readable medium encoded with a computer program for monitoring fatigue of a mechanical structure, the computer program comprising computer executable instructions for controlling programmable processing equipment to perform steps of:
retrieving data from a database containing predetermined response values each being associated with one of predetermined stress ranges and one of predetermined mean stresses, each of the response values expressing an upper limit for number of cycles of stress at a predetermined observation point of the mechanical structure in a situation in which the cycles have the predetermined stress range and the predetermined mean stress related to the response value under consideration, the upper limit corresponding to a predetermined survival probability of the mechanical structure,
repeatedly updating, for each of the response values, a stress history value expressing number of cycles occurred in a time-trend of the stress and having the predetermined stress range and the predetermined mean stress related to the response value under consideration, and
repeatedly updating a fatigue damage sum based on the response values and the stress history values related to the response values, the fatigue damage sum expressing cumulated fatigue damage of the mechanical structure.

16. (canceled)

17. The system according to claim 2, wherein the processing equipment is configured to compute the fatigue damage sum D according to the formula:
$$D = {\sum }_{i , j} \frac{{n}_{i , j} ( t )}{{N}_{i , j}} ,$$
where n_{i,j}(t) is the stress history value expressing the number of the cycles occurred in the time-trend of the stress and having the i^{th} predetermined stress range and the j^{th} predetermined mean stress, and N_{i,j} is the response value relating to the i^{th} predetermined stress range and to the j^{th} predetermined mean stress.

18. The system according to claim 3, wherein the processing equipment is configured to compute the fatigue damage sum D according to the formula:
$$D = {\sum }_{i , j} \frac{{n}_{i , j} ( t )}{{N}_{i , j}} ,$$
where n_{i,j}(t) is the stress history value expressing the number of the cycles occurred in the time-trend of the stress and having the i^{th} predetermined stress range and the j^{th} predetermined mean stress, and N_{i,j} is the response value relating to the i^{th} predetermined stress range and to the j^{th} predetermined mean stress.

19. The system according to claim 4, wherein the processing equipment is configured to compute the fatigue damage sum D according to the formula:
$$D = {\sum }_{i , j} \frac{{n}_{i , j} ( t )}{{N}_{i , j}} ,$$
where n_{i,j}(t) is the stress history value expressing the number of the cycles occurred in the time-trend of the stress and having the i^{th} predetermined stress range and the j^{th} predetermined mean stress, and N_{i,j} is the response value relating to the i^{th} predetermined stress range and to the j^{th} predetermined mean stress.

20. The system according to claim 5, wherein the processing equipment is configured to compute the fatigue damage sum D according to the formula:
$$D = {\sum }_{i , j} \frac{{n}_{i , j} ( t )}{{N}_{i , j}} ,$$
where n_{i,j}(t) is the stress history value expressing the number of the cycles occurred in the time-trend of the stress and having the i^{th} predetermined stress range and the j^{th} predetermined mean stress, and N_{i,j} is the response value relating to the i^{th} predetermined stress range and to the j^{th} predetermined mean stress.

21. The system according to claim 6, wherein the processing equipment is configured to compute the fatigue damage sum D according to the formula:
$$D = {\sum }_{i , j} \frac{{n}_{i , j} ( t )}{{N}_{i , j}} ,$$
where n_{i,j}(t) is the stress history value expressing the number of the cycles occurred in the time-trend of the stress and having the i^{th} predetermined stress range and the j^{th} predetermined mean stress, and N_{i,j} is the response value relating to the i^{th} predetermined stress range and to the j^{th} predetermined mean stress.
